(19) United States
(12) Patent Application Publication
(10) Pub. No.: US 2025/0301240 A1
(43) Pub. Date: Sep. 25, 2025

(54) IMAGE SENSOR AND METHOD OF MANUFACTURING COLOR ROUTER FOR IMAGE SENSOR

(71) Applicant: IUCF-HYU (INDUSTRY-UNIVERSITY COOPERATION FOUNDATION HANYANG UNIVERSITY), Seoul (KR)

(72) Inventors: Haejun CHUNG, Seoul (KR); Sangbin LEE, Seoul (KR); Jaehyun HONG, Seoul (KR)

(21) Appl. No.: 19/059,177

(22) Filed: Feb. 20, 2025

Related U.S. Application Data
(63) Continuation of application No. PCT/KR2024/095764, filed on Apr. 23, 2024.

(30) Foreign Application Priority Data
Mar. 19, 2024 (KR) 10-2024-0038071

(51) Int. Cl. H04N 25/77; H04N 25/13

(52) U.S. Cl. CPC H04N 25/77; H04N 25/13

(57) ABSTRACT

In an image sensor according to one embodiment, where a plurality of pixels are arranged, each of the plurality of pixels comprises: a light detection layer including a plurality of photodetectors; and a color router disposed on the light detection layer, with a first dielectric having a first dielectric constant and a second dielectric having a second dielectric constant arranged inside, wherein the image sensor further comprises: a plurality of interlayers disposed between the color routers of each of the plurality of pixels, to prevent light incident on one color router from crossing over to an adjacent color router.

### TECHNICAL FIELD

The present disclosure relates to an image sensor including a color router.

### BACKGROUND ART

Generally, an image sensor consists of an array of microlenses and a color filter. However, in this case, the loss of incident light reaches up to 66%, resulting in more than half of the light incident on the image sensor being lost.

To address this, recent studies have actively focused on image sensors based on color routers. A method has been proposed to replace the conventional color filter with a color router having a sub-wavelength structure, thereby avoiding the 66% loss of incident light.

However, conventional image sensors based on color routers are designed with periodic structures, which inevitably lead to optical crosstalk issues between adjacent pixels.

### SUMMARY

Provided are an image sensor capable of reducing optical crosstalk by introducing an interlayer between adjacent pixels during the implementation of a color router, and a method of manufacturing a color router that prevents interference between pixels by utilizing a Gaussian beam without an interlayer.

According to one embodiment of the present disclosure, An image sensor in which a plurality of pixels are arranged, wherein each of the plurality of pixels comprises a light detection layer including a plurality of photodetectors; and a color router disposed on the light detection layer, the color router having a first dielectric with a first dielectric constant and a second dielectric with a second dielectric constant arranged inside, and wherein the image sensor comprises a plurality of interlayers disposed between the color routers of each of the plurality of pixels, to prevent light incident on one color router from crossing over to an adjacent color router.
the light detection layer comprises a plurality of deep trench isolations (DTIs) disposed between the plurality of photodetectors to prevent light incident on one photodetector from crossing over to an adjacent photodetector.
each of the plurality of interlayers is disposed on a DTI positioned between two photodetectors that are adjacent to each other but belong to different pixels.
each of the plurality of interlayers is formed of SiO2 or metal.
   the metal is tungsten.
   the color router is provided with the first dielectric and includes a plurality of material layers stacked vertically, and each of the plurality of material layers forms a scattering pattern that includes a plurality of scatterers formed with the second dielectric.

According to another embodiment of the present disclosure, A method of manufacturing a color router disposed on a light detection layer comprising; a plurality of photodetectors to route signals of different wavelengths included in incident light to corresponding photodetectors, the method comprising generating a design for the structure of the color router; and forming the color router such that a first dielectric with a first dielectric constant and a second dielectric with a second dielectric constant are arranged inside, in accordance with the design, wherein the generating the design for the structure of the color router comprises: determining a candidate design in which dielectrics are arranged inside; and repeatedly performing a forward simulation, in which light is emitted through the candidate design to the plurality of photodetectors, and a backward simulation, in which light is emitted from the plurality of photodetectors to the candidate design, to adjust the dielectric distribution of the candidate design in a direction that maximizes the corresponding signal intensity at each of the plurality of photodetectors, and wherein the performing the forward simulation comprises: performing a simulation in which light emitted from a Gaussian beam light source is transmitted through the candidate design to the plurality of photodetectors.
the performing the forward and backward simulations comprises performing the simulations using a candidate design corresponding to a centrally positioned color router in a structure where color routers corresponding to individual pixels are repetitively arranged.
the performing the forward and backward simulations comprises placing a perfectly matched layer (PML) at the ends of a structure where color routers corresponding to individual pixels are repetitively arranged and performing the simulations.

According to the other embodiment of the present disclosure, A method of manufacturing a color router disposed on a light detection layer comprising a plurality of photodetectors to route signals of different wavelengths included in incident light to corresponding photodetectors, the method comprising; generating a design for the structure of the color router; and forming the color router such that a first dielectric with a first dielectric constant and a second dielectric with a second dielectric constant are arranged inside, in accordance with the design, wherein the generating the design for the structure of the color router comprises: determining a candidate design in which dielectrics are arranged inside; and repeatedly performing a forward simulation, in which light is emitted through the candidate design to the plurality of photodetectors, and a backward simulation, in which light is emitted from the plurality of photodetectors to the candidate design, to adjust the dielectric distribution of the candidate design in a direction that maximizes the corresponding signal intensity at each of the plurality of photodetectors, and wherein the performing the forward simulation and the backward simulation comprises: performing a simulation by placing an interlayer on the sides of the candidate design to prevent light incident on the candidate design from escaping through the sides of the candidate design.
the performing the forward simulation and the backward simulation comprises: performing the simulation by using an air gap as the interlayer.
the performing the forward simulation and the backward simulation comprises: performing the simulation by using SiO2 or metal as the interlayer.
the performing the forward simulation and the backward simulation comprises: performing the simulation by using tungsten as the interlayer.
the performing the forward simulation comprises: performing a simulation in which light emitted from a Gaussian beam light source is transmitted through the candidate design to the plurality of photodetectors.

According to an image sensor of one embodiment, optical crosstalk may be reduced by introducing an interlayer between adjacent pixels during the implementation of a color router. According to a method of manufacturing a color router of another embodiment, interference between pixels may be prevented by utilizing a Gaussian beam without an interlayer.

### BRIEF DESCRIPTION OF THE DRAWINGS

FIG. 1 is a cross-sectional view of an image sensor according to one embodiment.

FIG. 2 is a cross-sectional view of a case where a color router according to one embodiment is provided with a plurality of material layers.

FIG. 3 is a flowchart illustrating a method of manufacturing a color router according to one embodiment.

FIG. 4 is a flowchart illustrating a method of designing a color router according to one embodiment.

FIGS. 5 and 6 are diagrams for explaining a case where a color router according to one embodiment is designed using a backpropagation method.

FIG. 7 illustrates a case where a color router according to one embodiment is designed using a simulation with an air-gap interlayer.

FIG. 8 illustrates the routing effect in a case where a color router according to one embodiment is designed using a simulation with an air-gap interlayer.

FIG. 9 illustrates a case where a color router according to one embodiment is designed using a simulation with a tungsten interlayer.

FIG. 10 illustrates the routing effect in a case where a color router according to one embodiment is designed using a simulation with a tungsten interlayer.

FIG. 11 illustrates a case where a color router according to one embodiment is designed using a simulation with a Gaussian beam light source.

FIG. 12 illustrates the routing effect in a case where a color router according to one embodiment is designed using a simulation with a Gaussian beam light source.

FIG. 13 illustrates a case where a color router according to one embodiment is designed using a simulation with an interlayer and a Gaussian beam light source.

FIG. 14 illustrates a case where a color router according to one embodiment is designed in 3D using a simulation with an interlayer.

FIG. 15 illustrates the routing effect in a case where a color router according to one embodiment is designed in 3D using a simulation with an interlayer.

FIG. 16 illustrates a case where a color router according to one embodiment is designed in 3D using a simulation with a Gaussian beam light source.

FIG. 17 illustrates the routing effect in a case where a color router according to one embodiment is designed in 3D using a simulation with a Gaussian beam light source.

### DETAILED DESCRIPTION OF PREFERRED EMBODIMENT

The embodiments described in this specification and the configurations illustrated in the drawings represent merely preferred examples of the disclosed invention. As of the filing date of this application, various modifications and substitutions for the embodiments and drawings disclosed herein may exist.

Throughout this specification, when an element is described as being positioned ‘on’ another element, it includes both cases where the one element is directly on the other element and cases where additional elements may be interposed between them.

Additionally, the terms used in this specification are intended to describe the embodiments and are not intended to limit and/or restrict the scope of the disclosed invention. Unless explicitly stated otherwise, singular expressions include their plural forms. In this specification, terms such as ‘comprise’ or ‘have’ are intended to indicate the presence of features, numbers, steps, actions, components, parts, or combinations thereof as described in the specification, but do not preclude the presence or addition of one or more other features, numbers, steps, actions, components, parts, or combinations thereof.

Additionally, terms such as ‘first’ and ‘second,’ which include ordinals, may be used in this specification to describe various components. However, these components are not limited by these terms, which are used solely to distinguish one component from another. For example, without departing from the scope of the present invention, a ‘first’ component may be referred to as a ‘second’ component, and similarly, a ‘second’ component may be referred to as a ‘first’ component.

Hereinafter, embodiments of the present invention will be described in detail with reference to the accompanying drawings.

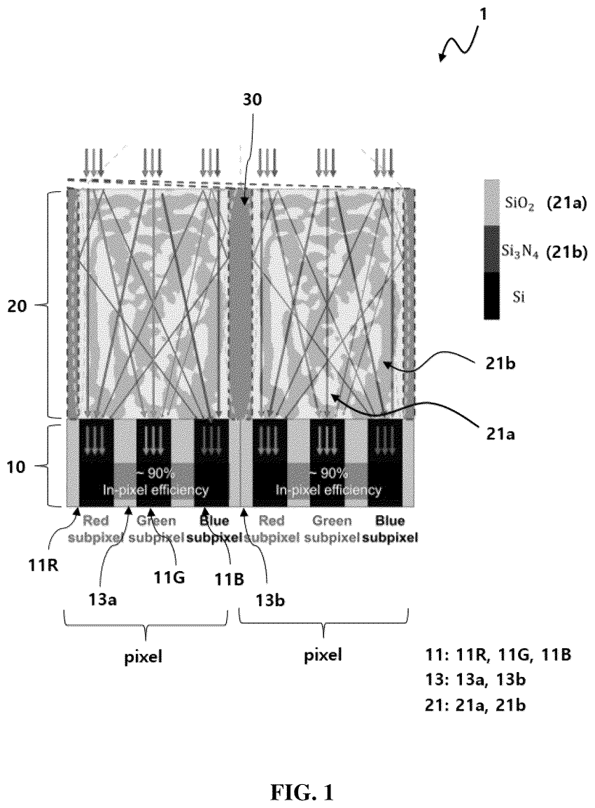

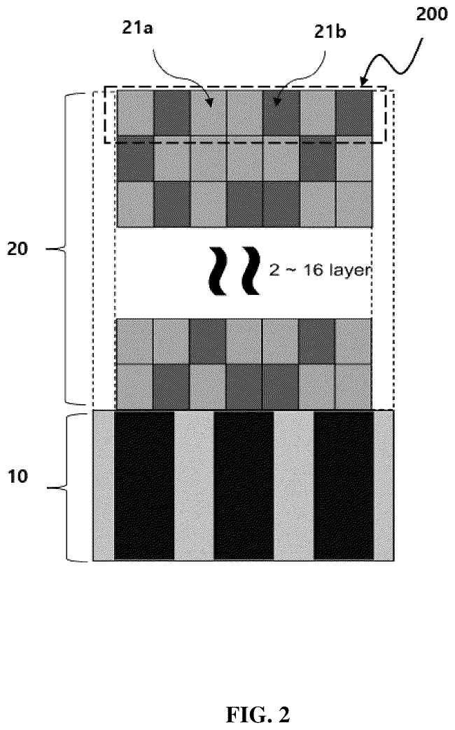

FIG. 1 is a cross-sectional view of an image sensor according to one embodiment, and FIG. 2 is a cross-sectional view of a case where a color router according to one embodiment is provided with a plurality of material layers.

Referring to FIG. 1, an image sensor 1 according to one embodiment may include a plurality of pixels arranged, where each pixel includes a red subpixel, a green subpixel, and a blue subpixel.

In this case, each of the plurality of pixels includes a light detection layer 10 comprising a plurality of photodetectors 11R, 11G, 11B; and 11 and a color router 20 disposed on the light detection layer 10 to route signals corresponding to different wavelength regions of light incident thereon to respective photodetectors 11.

The light detection layer 10 according to one embodiment may include deep trench isolation (DTI) 13 disposed between the plurality of photodetectors 11 to prevent light incident on one photodetector from crossing over to an adjacent photodetector.

In this case, the DTI 13 includes a first DTI 13a disposed between the plurality of photodetectors 11 within a single pixel, and a second DTI 13b disposed between two photodetectors included in adjacent but different pixels.

For example, the first DTI 13a may be positioned between the red photodetector 11R and the green photodetector 11G, and between the green photodetector 11G and the blue photodetector 11B within a single pixel. Additionally, the second DTI 13b may be positioned between the blue photodetector 11B of one pixel and the red photodetector 11R of an adjacent pixel.

In FIG. 1, the photodetector 11 is exemplified as Si, and the DTI 13 is exemplified as SiO2. However, any known type of material that may be used as a photodetector and DTI may be employed in the present disclosure without limitation.

Among the light incident on the color router 20, red light may be routed to the red photodetector 11R, green light may be routed to the green photodetector 11G, and blue light may be routed to the blue photodetector 11B.

The color router 20 may include a first dielectric 21a with a first dielectric constant and a second dielectric with a second dielectric constant arranged inside, thereby allowing signals corresponding to different wavelength regions to be routed to respective photodetectors 11.

For example, as illustrated in FIG. 2, the color router 20 may be provided with the first dielectric 21a and include a plurality of vertically stacked material layers 200, each of which may form a scattering pattern that includes a plurality of scatterers formed with the second dielectric 21b.

Specifically, one material layer 200 may have the first dielectric 21a as its body, with the second dielectric 21b filling the empty spaces within the body to form a scattering pattern layer.

In FIG. 2, the plurality of material layers 200 is exemplified as comprising 2 to 16 layers. However, there is no limitation on the number of material layers 200.

The color router 20 may be designed with an internal dielectric arrangement such that signals corresponding to different wavelength regions may be routed to respective photodetectors 11. This will be described in further detail later.

In FIG. 1, the first dielectric 21a is exemplified as SiO2, and the second dielectric 21b is exemplified as Si3N4. However, any two types of dielectrics with different dielectric properties may be used in the present disclosure without limitation.

In addition, an image sensor 1 according to one embodiment may include a plurality of interlayers 30 disposed between the color routers 20 of each of the plurality of pixels, to prevent light incident on one color router from crossing over to an adjacent color router.

Through this configuration, the image sensor 1 may reduce optical crosstalk between adjacent pixels even when implementing the color router 20.

In this case, each of the plurality of interlayers 30 may be disposed on the second DTI 13b, which is positioned between two photodetectors included in adjacent but different pixels.

In addition, the plurality of interlayers 30 may, according to an embodiment, be provided as air gaps. That is, the plurality of interlayers 30 may be formed as air gaps with the lowest refractive index (n=1.0), thereby reducing optical crosstalk between adjacent pixels.

Additionally, the plurality of interlayers 30 may, according to an embodiment, be formed of SiO2 or metal. Through this configuration, the plurality of interlayers 30 may act as physical barriers instead of empty spaces, reducing optical crosstalk between adjacent pixels.

For example, tungsten may be used as the metal forming the plurality of interlayers 30, considering factors such as CMOS compatibility. However, the metal forming the plurality of interlayers 30 is not limited to tungsten and may include any metal with high CMOS compatibility without limitation.

The following describes in detail the process of manufacturing the color router 20.

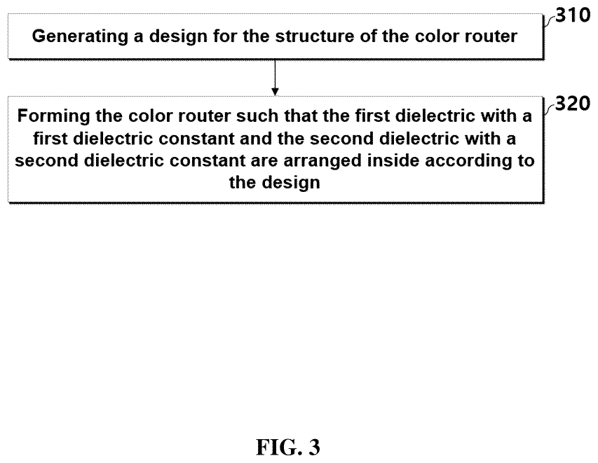

FIG. 3 is a flowchart illustrating a method of manufacturing the color router 20 according to one embodiment.

Referring to FIG. 3, the method of manufacturing the color router 20 according to one embodiment may include generating a design for the structure of the color router 20 (310), and forming the color router 20 such that the first dielectric 21a with a first dielectric constant and the second dielectric 21b with a second dielectric constant are arranged inside according to the design (320).

For example, when a design for the structure of the color router 20 is generated, the color router 20 may be formed by arranging the first dielectric 21a and the second dielectric 21b to correspond to the dielectric arrangement in the design. Specifically, as shown in FIG. 2, a plurality of material layers 200 provided with the first dielectric 21a may be stacked, and each of the stacked material layers 200 may form a scattering pattern of the second dielectric 21b corresponding to the dielectric arrangement in the design.

The following describes in detail the process of designing the color router 20.

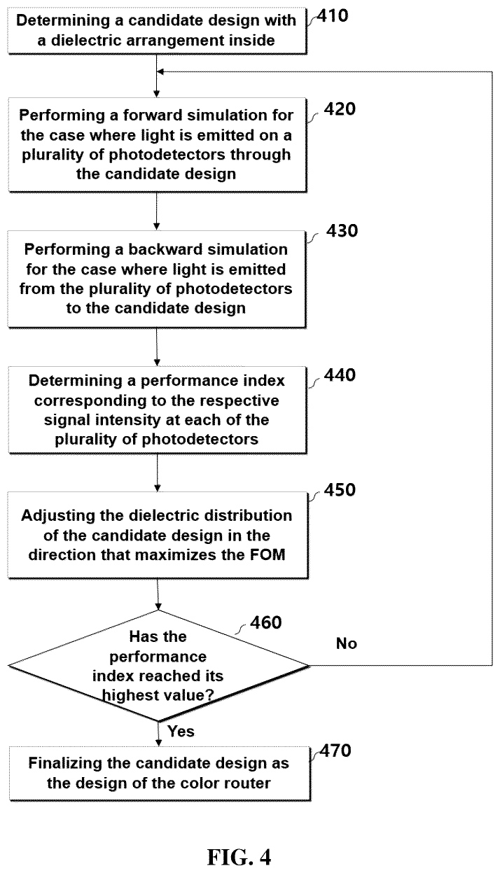

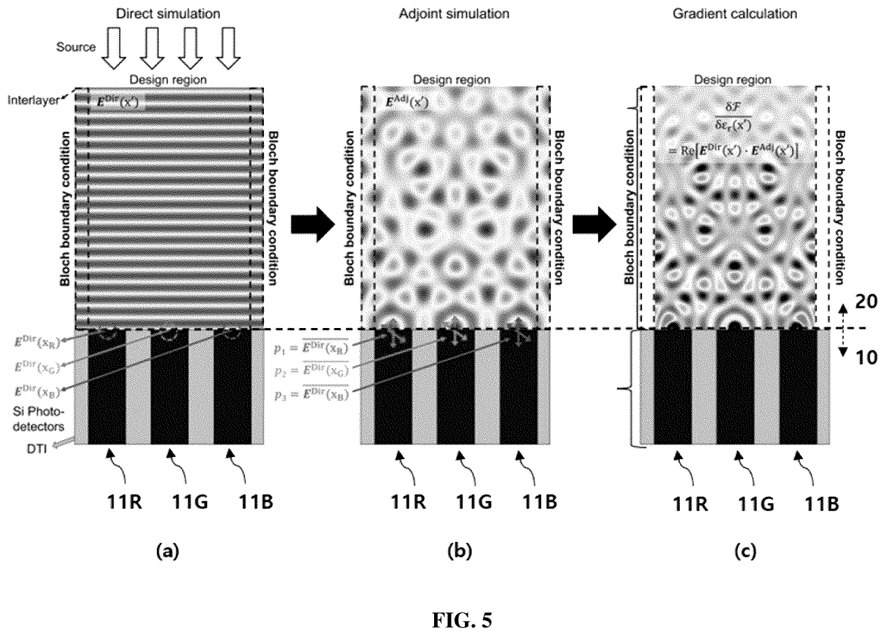

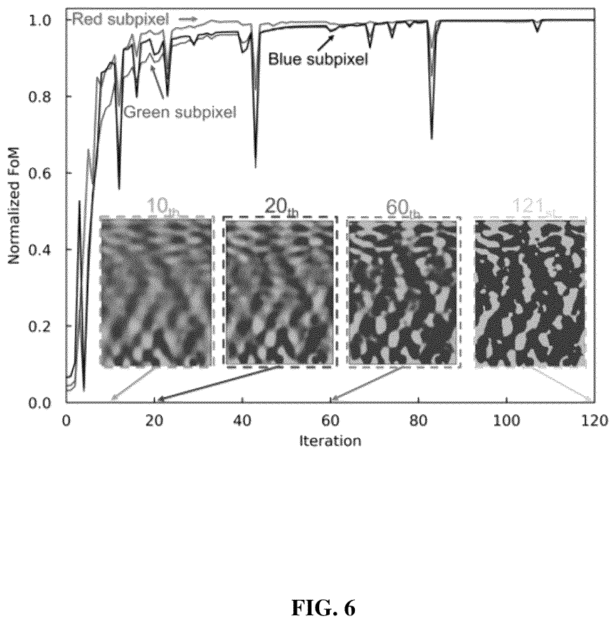

FIG. 4 is a flowchart illustrating a method of designing the color router 20 according to one embodiment, and FIGS. 5 and 6 are diagrams for explaining a case where the color router 20 according to one embodiment is designed using a backpropagation method.

The design of the color router 20 is simulated using electromagnetic simulations by a known type of electronic device. For example, the simulation may be a full-wave simulation using the finite-difference time-domain (FDTD) method. However, the type of electromagnetic simulation is not limited and may include finite-difference frequency-domain or finite element methods.

Referring to FIG. 4, the method of designing the color router 20 according to one embodiment may include determining a candidate design with a dielectric arrangement inside (410), performing a forward simulation for the case where light is emitted on a plurality of photodetectors 11 through the candidate design (420), performing a backward simulation for the case where light is emitted from the plurality of photodetectors 11 to the candidate design (430), and determining a performance index corresponding to the respective signal intensity at each of the plurality of photodetectors 11 (440).

Thus, the method of designing the color router 20 may employ a backpropagation method (adjoint method) capable of calculating the gradients for all structural degrees of freedom within a pair of forward and backward simulations, thereby optimizing the metastructure of the optical system.

In the forward simulation, as illustrated in (a) of FIG. 5, light is emitted through the candidate design to a plurality of photodetectors 11, and the electric field intensities (E^{dir}(x_{R}), E^{dir}(x_{G}), E^{dir}(x_{B})) at the centers of the subpixels corresponding to each photosensitive region (the centers of photodetectors 11) (x_{R}, x_{G}, x_{B}) may be determined.

In addition, in the backward simulation, as illustrated in (b) of FIG. 5, light is emitted from the plurality of photodetectors 11 to the candidate design, and the electric field intensity (F^{adj}(x′)) at each point (x′) within the candidate design of the color router 20 may be determined.

Specifically, in the backward simulation, the backpropagation source (J_{adj}) may be determined based on <Equation 1>. Dipoles (P₁, P₂, P₃; P_{adj}), whose magnitudes correspond to the conjugate fields E̅^̅{̅d̅i̅r̅}̅(̅x̅_̅{̅R̅}̅)̅,̅ E̅^̅{̅d̅i̅r̅}̅(̅x̅_̅{̅G̅}̅)̅,̅ E̅^̅{̅d̅i̅r̅}̅(̅x̅_̅{̅B̅}̅)̅, are backpropagated through the candidate design of the color router 20, and the electric field intensity (F^{adj}(x′)) at each point (x′) within the candidate design may be determined.

$${J}_{adj} = - {iwP}_{adj} = - iw \partial F / \partial E \qquad [ Equation 1 ]$$

At this time, F is the performance index (figure of merit, FOM) for intensity maximization at the center of the subpixel corresponding to the photosensitive region of each wavelength, and as shown in <Equation 2>, it may be the sum of the corresponding signal intensities at each of the plurality of photodetectors 11.

$$F = α {\int }_{λ = {R}_{m i n}}^{λ = {R}_{m ax}} {\vert E ( {x}_{R} , λ ) \vert}^{2} + β {\int }_{λ = {G}_{m i n}}^{λ = {G}_{m ax}} {\vert E ( {x}_{G} , λ ) \vert}^{2} + γ {\int }_{λ = {B}_{m i n}}^{λ = {B}_{m ax}} {\vert E ( {x}_{B} , λ ) \vert}^{2} \qquad [ Equation 2 ]$$

α, β, and γ are normalization factors used to ensure uniform optimization across each wavelength band, as the intensity of light focused at the designated focal point varies due to differences in the airy disk profile depending on the wavelength.

In the simulation, as illustrated in (c) of FIG. 5, the gradient of the performance index (FOM) with respect to changes in the internal permittivity ∈ᵣ(x′) of the candidate design may be calculated using <Equation 3>.

That is, the simulation aims to find the dielectric distribution within the candidate design that maximizes the performance index (FOM). The FOM value is measured through forward simulation, and by utilizing Lorentz reciprocity to position the backpropagation source in the region where the FOM is measured, the backward simulation is performed. This allows the calculation of the rate of change in the FOM corresponding to changes in the dielectric distribution within the candidate design.

In the simulation, the dielectric distribution of the candidate design is adjusted in the direction that maximizes the FOM (450). Steps 420 through 450 are repeated until the number of simulations reaches the predefined value (e.g., step 460), thereby finalizing the candidate design as the design of the color router 20 (470). At this time, the predefined number of simulations is a value set in advance during the design stage and may be configured to various values by the user.

As illustrated in FIG. 6, by repeatedly performing forward simulations (420) and backward simulations (430) until the FOM reaches its maximum, the candidate design is transformed into a fully binary material composed of the first dielectric 21a and the second dielectric 21b.

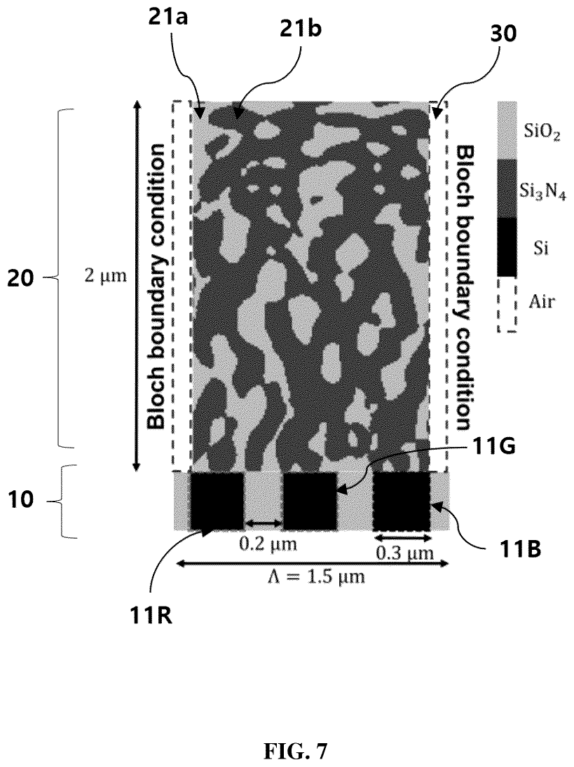

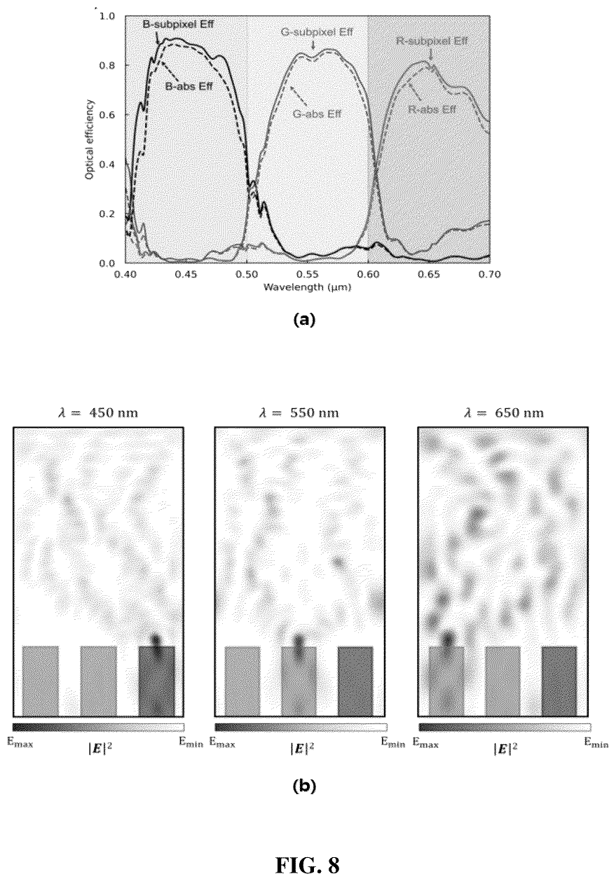

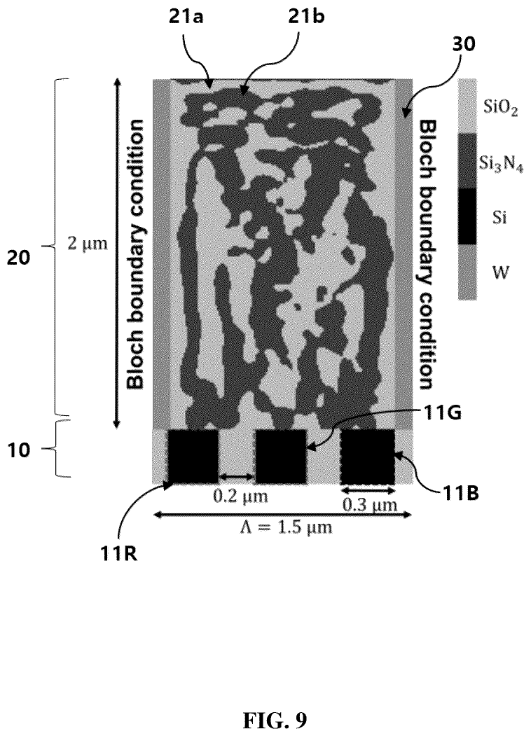

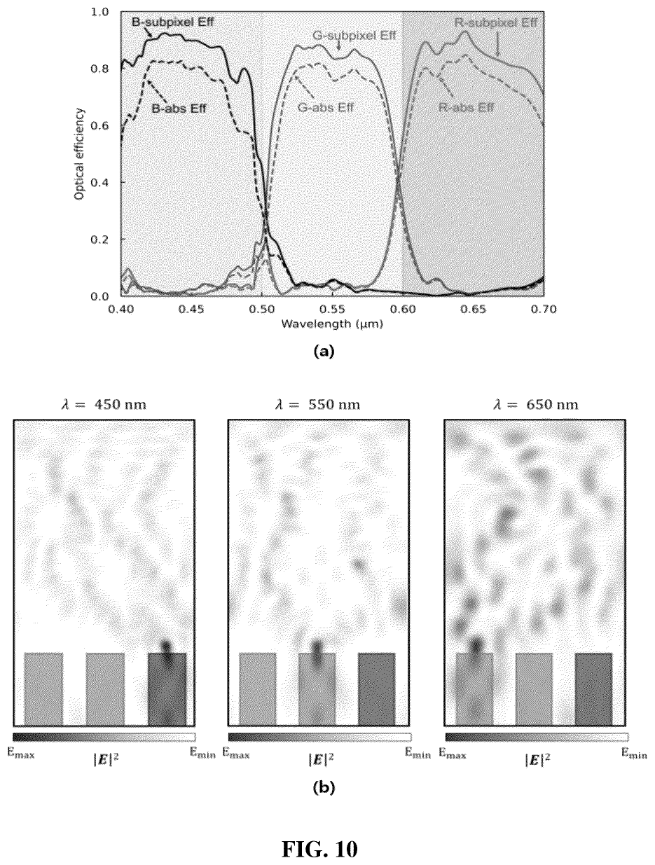

FIG. 7 illustrates a case where the color router 20 according to one embodiment is designed using a simulation with an interlayer 30 formed as an air gap, FIG. 8 illustrates the routing effect in such a case. FIG. 9 illustrates a case where the color router 20 according to one embodiment is designed using a simulation with an interlayer 30 formed of tungsten, and FIG. 10 illustrates the routing effect in such a case.

Referring to FIGS. 7 through 10, in the design method of the color router 20 according to one embodiment, performing forward and backward simulations may include placing an interlayer 30 at the sides of the candidate design to ensure that light incident on the candidate design of the color router 20 does not escape through the sides of the candidate design during the simulation.

Thus, the design method of the color router 20 according to one embodiment may determine the dielectric distribution inside the candidate design that suppresses optical crosstalk between repetitive pixels by placing an interlayer 30 at the sides of the candidate design of the color router 20 and performing simulations.

In the forward simulation using the interlayer 30, depending on the embodiment, the light of a plane wave may be simulated to pass through the candidate design and be incident on the photodetectors 11. Alternatively, depending on the embodiment, the light from a Gaussian beam light source may be simulated to pass through the candidate design and be incident on the photodetectors 11. The embodiment utilizing both the interlayer 30 and the Gaussian beam light source will be described in detail later.

For example, as illustrated in FIG. 7, the design method of the color router 20 according to one embodiment may perform simulations by placing an air gap as the interlayer 30 at the sides of the candidate design of the color router 20. In other words, performing forward and backward simulations may include conducting simulations with the interlayer 30 formed as an air gap.

When the color router 20 is designed using a simulation with an interlayer 30 formed as an air gap, as shown in (a) of FIG. 8, light is routed to the corresponding photodetectors 11 based on the wavelength. This results in high optical efficiency for each of the red, green, and blue subpixels, even in periodic structures. Here, the subpixel efficiency (subpixel Eff) refers to the ratio of light transmitted to the appropriately colored subpixel based on the wavelength out of the total light transmitted through the entire photosensitive region. The absolute efficiency (abs Eff) refers to the ratio of light transmitted to the appropriately colored subpixel based on the wavelength out of the total light incident on the entire color router 20.

Specifically, as illustrated in (b) of FIG. 8, when the color router 20 is designed using a simulation with an interlayer 30 formed as an air gap, the intensity profile confirms that the light is well-focused on the corresponding photosensitive regions with minimal color crosstalk.

In addition, the design method of the color router 20 according to one embodiment may include performing simulations by placing an interlayer 30 formed of SiO2 or metal at the sides of the candidate design of the color router 20. In other words, performing forward and backward simulations may include conducting simulations with the interlayer 30 formed of SiO2 or metal.

For example, performing forward and backward simulations may include, as illustrated in FIG. 9, conducting simulations with the interlayer 30 formed of tungsten. In this case, in the optimized design of the color router 20, the second dielectric 21b is positioned vertically without touching the interlayer 30. This optimization ensures that the light is guided downward without touching the interlayer 30, due to the high absorption rate of tungsten.

When the color router 20 is designed using a simulation with an interlayer 30 formed of tungsten, as illustrated in (a) of FIG. 10, light is routed to the corresponding photodetectors 11 based on the wavelength. This results in high optical efficiency for each of the red, green, and blue subpixels, even in periodic structures.

Specifically, as illustrated in (b) of FIG. 10, when the color router 20 is designed using a simulation with an interlayer 30 formed of tungsten, the intensity profile confirms that the light is well-focused on the corresponding photosensitive regions with minimal color crosstalk.

The above describes a method of designing the color router 20 using the interlayer 30. The following describes a method of designing the color router 20 using a Gaussian beam light source.

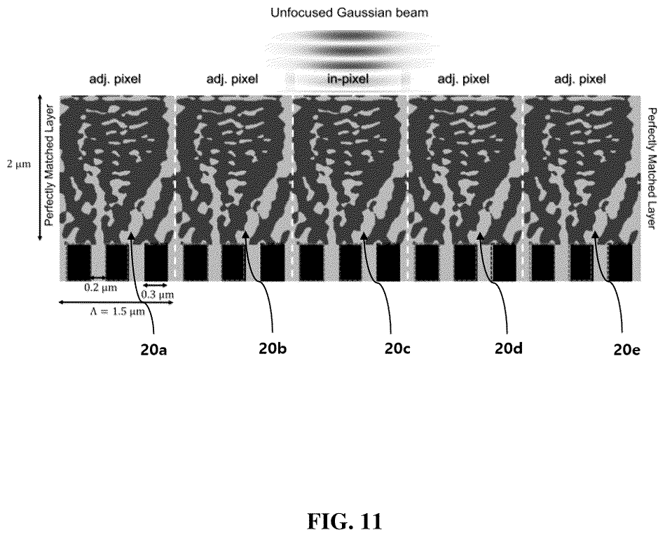

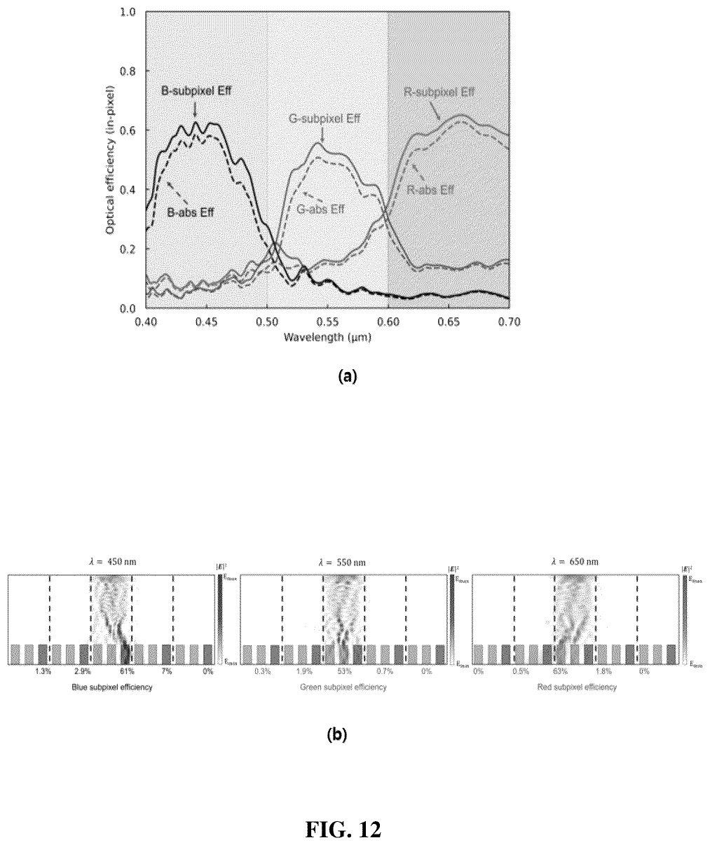

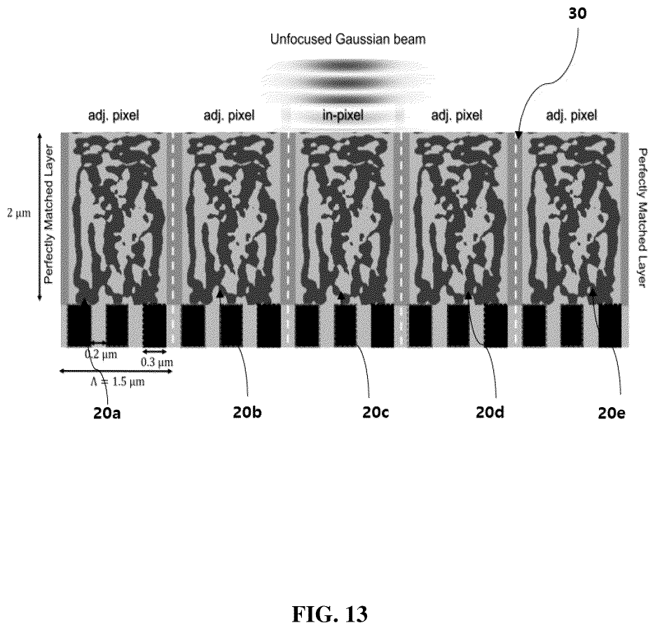

FIG. 11 illustrates a case where the color router 20 according to one embodiment is designed using a simulation with a Gaussian beam light source. FIG. 12 illustrates the routing effect in such a case, and FIG. 13 illustrates a case where the color router 20 according to one embodiment is designed using a simulation with both an interlayer 30 and a Gaussian beam light source.

Referring to FIG. 11, the method of designing the color router 20 according to one embodiment may include performing a forward simulation in which light emitted from a Gaussian beam light source is transmitted through the candidate design and emitted on the plurality of photodetectors 11.

In the optimization of conventional color routers 20, it was impossible to distinguish between pixels without using an interlayer 30 when using plane waves as incident waves in a periodic environment, necessitating physical constraints to control optical crosstalk between pixels.

In the forward and backward simulations according to one embodiment, simulations are performed using the centrally positioned color router 20c in a structure where color routers 20 corresponding to individual pixels are repetitively arranged as the candidate design. By irradiating the candidate design corresponding to the centrally positioned color router 20c with a Gaussian beam light source, a plane wave incident only on the single centrally located pixel may be simulated, thereby increasing the design freedom compared to when an interlayer 30 is used.

For example, as illustrated in FIG. 11, the forward and backward simulations may be performed by irradiating the Gaussian beam light source on the candidate design corresponding to the centrally positioned color router 20c among the five repetitively arranged color routers 20a, 20b, 20c, 20d, and 20e.

In this case, in the backpropagation method, the performance index (FOM) is measured only at the central pixel targeted by the Gaussian beam. With each iteration, the dielectric distribution of the candidate design corresponding to the central pixel is modified, and as a result, the designs of the remaining repetitively arranged color routers are likewise modified.

According to one embodiment, performing the forward and backward simulations may include placing a perfectly matched layer (PML) at the ends of a structure where color routers 20 corresponding to individual pixels are repetitively arranged. For example, as illustrated in FIG. 11, the simulation may be implemented by placing PMLs at the ends of the color routers 20a and 20e among the five repetitively arranged color routers 20a, 20b, 20c, 20d, and 20e, thereby restricting periodicity within a limited region during the simulation.

When the color router 20 is designed using a simulation in which a Gaussian beam light source is irradiated onto the centrally positioned color router in a structure where color routers are repetitively arranged, as illustrated in (a) of FIG. 12, light is routed to the corresponding photodetectors 11 based on the wavelength. This results in high optical efficiency for each of the red, green, and blue subpixels, even in periodic structures.

Specifically, as illustrated in (b) of FIG. 12, when the color router 20 is designed using a simulation in which a Gaussian beam light source is irradiated onto the centrally positioned color router in a structure where color routers are repetitively arranged, the intensity profile for five periods of the optimized image sensor 1 at three representative wavelengths demonstrates that incident light is successfully routed to the corresponding subpixels without spreading to adjacent pixels. Thus, the optimized structure using a Gaussian beam light source suppresses optical crosstalk between pixels and exhibits high efficiency within pixels without the use of an interlayer 30.

In addition, the design method of the color router 20 according to one embodiment may include performing simulations using both the interlayer 30 and the Gaussian beam light source.

For example, as illustrated in FIG. 13, the simulation may be performed by positioning the interlayer 30 between the five repetitively arranged color routers 20a, 20b, 20c, 20d, and 20e, and by irradiating the Gaussian beam light source on the candidate design corresponding to the centrally positioned color router 20c among the five repetitively arranged color routers 20a, 20b, 20c, 20d, and 20e.

The above describes the design of the 2D color router 20. The following describes the design of the 3D color router 20. The design method of the 3D color router 20 utilizes the content described in FIGS. 1 through 13 for the 2D color router 20. The differences that may arise during the 3D design process compared to the previous descriptions are explained below.

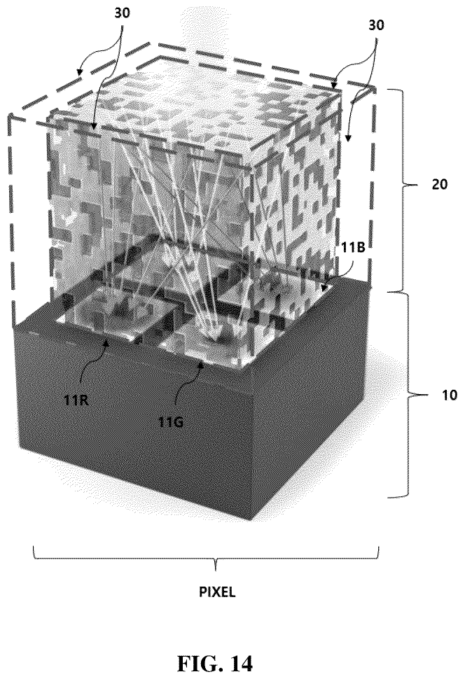

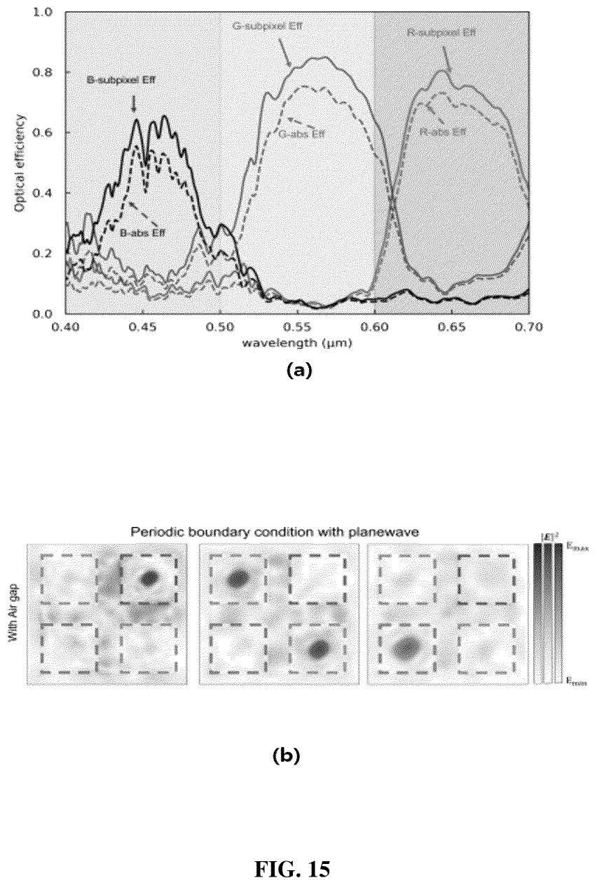

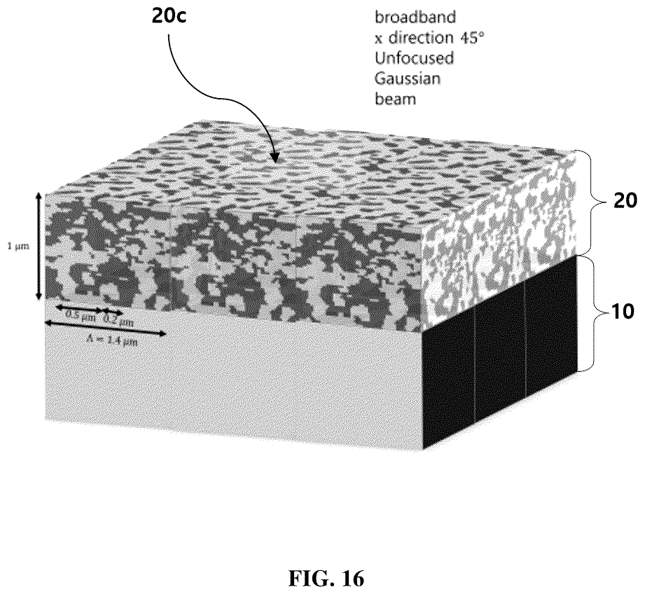

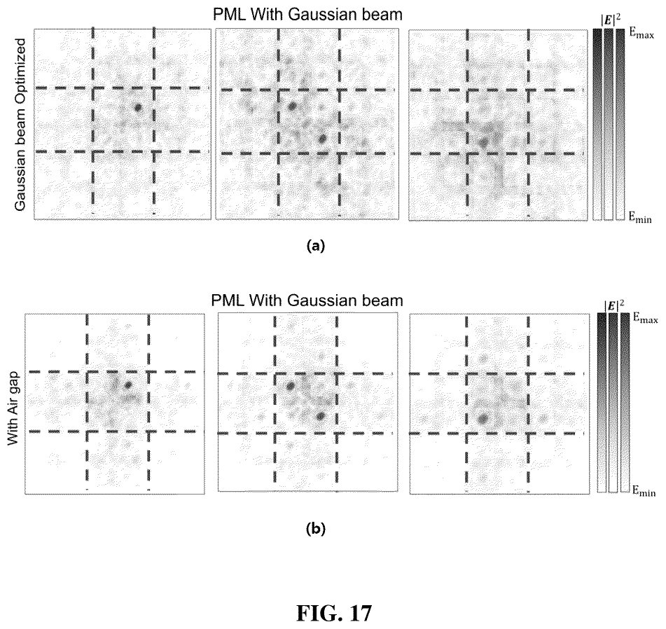

FIG. 14 illustrates a case where the color router 20 according to one embodiment is designed in 3D using a simulation with the interlayer 30. FIG. 15 illustrates the routing effect in such a case. FIG. 16 illustrates a case where the color router 20 according to one embodiment is designed in 3D using a simulation with a Gaussian beam light source. FIG. 17 illustrates the routing effect in such a case.

The design of the 3D color router 20, unlike the design of the 2D color router 20, allows the dielectric distribution to vary at each position and across all three dimensions within the candidate design.

In this case, as illustrated in FIG. 14, the plurality of photodetectors 11 may be arranged in a Bayer pattern, which includes one red photodetector 11R, two green photodetectors 11G, and one blue photodetector 11B. However, the pattern in which the plurality of photodetectors 11 is arranged is not limited and may include any known configuration.

In the design method of the color router 20 according to one embodiment, the performance index (FOM) is used to maximize intensity at the center of each subpixel. Since there are twice as many green subpixels as subpixels of other colors, the intensities corresponding to the two green subpixels are summed and then divided by two to ensure uniform optimization across colors.

That is, the performance index (FOM) used for designing the 3D color router 20 may be as shown in <Equation 3>,

$$F = α {\int }_{λ = {R}_{m i n}}^{λ = {R}_{m ax}} {\vert E ( {x}_{R} , λ ) \vert}^{2} + β {\int }_{λ = {G}_{m i n}}^{λ = {G}_{ma x}} \frac{{\vert E ( {x}_{{G}_{1}} , λ ) \vert}^{2} + {\vert E ( {x}_{{G}_{2}} , λ ) \vert}^{2}}{2} + γ {\int }_{λ = {B}_{m i n}}^{λ = {B}_{m ax}} {\vert E ( {x}_{B} , λ ) \vert}^{2} \qquad [ Equation 3 ]$$

Here, x_{G1},x_{G2} represent the centers of the two diagonally arranged green subpixels, respectively, and E^{λ} denotes the electric field intensity corresponding to the wavelength of the incident wave.

In the design method of the 3D color router 20 according to one embodiment, as illustrated in FIG. 14, the color router 20 corresponding to a single pixel is used as the candidate design. By repeatedly performing forward and backward simulations on the candidate design, the dielectric distribution within the 3D candidate design may be optimized.

In this case, interlayers 30 may be placed on the four sides of the candidate design corresponding to the 3D color router 20, such that the interlayers 30 surround the color router. This design enables the execution of simulations while eliminating optical crosstalk between pixels.

When the 3D color router 20 is designed using a simulation with interlayers 30, as illustrated in (a) of FIG. 15, light is routed to the corresponding photodetectors 11 based on the wavelength, resulting in high optical efficiency for each of the red, green, and blue subpixels even in periodic structures.

Specifically, as illustrated in (b) of FIG. 15, when the 3D color router 20 is designed using a simulation with interlayers 30, the intensity profile confirms that the light is well-focused on the corresponding photosensitive regions with minimal color crosstalk.

In addition, the design method of the 3D color router 20 according to one embodiment may be performed using simulations with a Gaussian beam light source.

For example, as illustrated in FIG. 16, the design method of the 3D color router 20 according to one embodiment may involve simulations where nine 3D color routers 20 are arranged in a 3×3 repetitive structure. The simulation is performed using the centrally positioned color router 20c as the candidate design. By irradiating the candidate design corresponding to the central color router 20c with a Gaussian beam light source, a plane wave incident only on the single central pixel may be mimicked, thereby increasing design freedom compared to when an interlayer 30 is used.

In this case, in the backpropagation method, the performance index (FOM) is measured only at the central pixel targeted by the Gaussian beam. With each iteration, the dielectric distribution of the candidate design corresponding to the central pixel is modified, and consequently, the designs of the remaining repetitively arranged color routers are also modified accordingly.

According to one embodiment, performing the forward and backward simulations may include placing a perfectly matched layer (PML) at the ends of a structure where color routers 20 corresponding to individual pixels are repetitively arranged.

When the 3D color router 20 is designed using simulations in which a Gaussian beam light source is irradiated onto the centrally positioned color router in a repetitive structure, as illustrated in (a) of FIG. 17, the intensity profile confirms that the light is well-focused on the corresponding photosensitive regions with minimal color crosstalk. This optimized structure using a Gaussian beam light source suppresses optical crosstalk between pixels and demonstrates high intra-pixel efficiency without using an interlayer 30.

Additionally, the design method of the color router 20 according to one embodiment may include performing simulations using both the interlayer 30 and the Gaussian beam light source.

For example, the simulation may be performed by positioning an interlayer between the repetitively arranged 3D color routers 20 and irradiating the Gaussian beam light source on the candidate design corresponding to the central color router 20c among the repetitively arranged 3D color routers.

In this case, as illustrated in (b) of FIG. 17, the intensity profile confirms that the light is well-focused on the corresponding photosensitive regions with minimal color crosstalk. Compared to the result shown in (a) of FIG. 17, which uses only the Gaussian beam light source for simulation, further improvement in optical crosstalk reduction may be observed.

As described above, the disclosed embodiments have been explained with reference to the accompanying drawings. It will be understood by those skilled in the art that the present invention may be implemented in other forms different from the disclosed embodiments without altering the technical spirit or essential characteristics of the invention. The disclosed embodiments are illustrative and should not be construed as limiting.

### DESCRIPTION OF REFERENCE NUMERALS AND SYMBOLS

1: Image sensor
10: Light detection layer
11: Photodetector
13: Deep Trench Isolation (DTI)
20: Color router
21: Dielectric
30: Interlayer

1. An image sensor in which a plurality of pixels are arranged,
wherein each of the plurality of pixels comprises:
a light detection layer including a plurality of photodetectors; and
a color router disposed on the light detection layer, the color router having a first dielectric with a first dielectric constant and a second dielectric with a second dielectric constant arranged inside, and
wherein the image sensor comprises:
a plurality of interlayers disposed between the color routers of each of the plurality of pixels, to prevent light incident on one color router from crossing over to an adjacent color router.

2. The image sensor according to claim 1,
wherein the light detection layer comprises:
a plurality of deep trench isolations (DTIs) disposed between the plurality of photodetectors to prevent light incident on one photodetector from crossing over to an adjacent photodetector.

3. The image sensor according to claim 2,
wherein each of the plurality of interlayers is disposed on a DTI positioned between two photodetectors that are adjacent to each other but belong to different pixels.

4. The image sensor according to claim 1,
wherein each of the plurality of interlayers is provided as an air gap.

5. The image sensor according to claim 1,
wherein each of the plurality of interlayers is formed of SiO₂ or metal.

6. The image sensor according to claim 5,
wherein the metal is tungsten.

7. The image sensor according to claim 1,
wherein the color router is provided with the first dielectric and includes a plurality of material layers stacked vertically,
and each of the plurality of material layers forms a scattering pattern that includes a plurality of scatterers formed with the second dielectric.

8. A method of manufacturing a color router disposed on a light detection layer comprising a plurality of photodetectors to route signals of different wavelengths included in incident light to corresponding photodetectors, the method comprising:
generating a design for the structure of the color router; and
forming the color router such that a first dielectric with a first dielectric constant and a second dielectric with a second dielectric constant are arranged inside, in accordance with the design,
wherein the generating the design for the structure of the color router comprises:
determining a candidate design in which dielectrics are arranged inside; and
repeatedly performing a forward simulation, in which light is emitted through the candidate design to the plurality of photodetectors, and a backward simulation, in which light is emitted from the plurality of photodetectors to the candidate design, to adjust the dielectric distribution of the candidate design in a direction that maximizes the corresponding signal intensity at each of the plurality of photodetectors, and
wherein the performing the forward simulation comprises:
performing a simulation in which light emitted from a Gaussian beam light source is transmitted through the candidate design to the plurality of photodetectors.

9. The method of manufacturing a color router according to claim 8,
wherein the performing the forward and backward simulations comprises performing the simulations using a candidate design corresponding to a centrally positioned color router in a structure where color routers corresponding to individual pixels are repetitively arranged.

10. The method of manufacturing a color router according to claim 9,
wherein the performing the forward and backward simulations comprises placing a perfectly matched layer (PML) at the ends of a structure where color routers corresponding to individual pixels are repetitively arranged and performing the simulations.

11. A method of manufacturing a color router disposed on a light detection layer comprising a plurality of photodetectors to route signals of different wavelengths included in incident light to corresponding photodetectors, the method comprising:
generating a design for the structure of the color router; and
forming the color router such that a first dielectric with a first dielectric constant and a second dielectric with a second dielectric constant are arranged inside, in accordance with the design,
wherein the generating the design for the structure of the color router comprises:
determining a candidate design in which dielectrics are arranged inside; and
repeatedly performing a forward simulation, in which light is emitted through the candidate design to the plurality of photodetectors, and a backward simulation, in which light is emitted from the plurality of photodetectors to the candidate design, to adjust the dielectric distribution of the candidate design in a direction that maximizes the corresponding signal intensity at each of the plurality of photodetectors, and
wherein the performing the forward simulation and the backward simulation comprises:
performing a simulation by placing an interlayer on the sides of the candidate design to prevent light incident on the candidate design from escaping through the sides of the candidate design.

12. The method of manufacturing a color router according to claim 11,
wherein the performing the forward simulation and the backward simulation comprises:
performing the simulation by using an air gap as the interlayer.

13. The method of manufacturing a color router according to claim 11,
wherein the performing the forward simulation and the backward simulation comprises:
performing the simulation by using SiO₂ or metal as the interlayer.

14. The method of manufacturing a color router according to claim 13,
wherein the performing the forward simulation and the backward simulation comprises:
performing the simulation by using tungsten as the interlayer.

15. The method of manufacturing a color router according to claim 11,
wherein the performing the forward simulation comprises:
performing a simulation in which light emitted from a Gaussian beam light source is transmitted through the candidate design to the plurality of photodetectors.
